(19) United States
(12) Patent Application Publication
(10) Pub. No.: US 2023/0243709 A1
(43) Pub. Date: Aug. 3, 2023

(54) CALIBRATION OF AN ELECTRONIC ASSEMBLY DURING A MANUFACTURING PROCESS

(71) Applicant: Siemens Aktiengesellschaft, München (DE)

(72) Inventors: Michael Lebacher, Töging am Inn (DE); Johanna Bronner, München (DE); Timo Rieskamp, München (DE); Peter Fischer, Schwandorf (DE); Gunter Griessbach, Gelenau (DE); Robert Weikert, Burggriesbach (DE); Lukas Wabro, Poppenricht (DE)

(21) Appl. No.: 18/101,172

(22) Filed: Jan. 25, 2023

(30) Foreign Application Priority Data
Feb. 3, 2022 (EP) 22154952.0

(51) Int. Cl. G01K 15/00

(52) U.S. Cl. CPC G01K 15/005

(57) ABSTRACT

A method for calibrating an electronic assembly during a manufacturing process is provided, including the steps: determining a calibration value for the assembly which for a predefined input value gives a deviation between an actual output value output by the assembly and a predefined desired output value, transmitting the calibration value to the assembly, and storing the calibration value in the assembly, wherein the calibration value of the assembly is determined by a machine learning method executed in a calibration device, and the machine learning method is trained by training data, which include historical calibration values of a plurality of assemblies of the same type and parameters of assemblies of the same type, which are dependent on the manufacturing process and/or express physical properties.

### CROSS-REFERENCE TO RELATED APPLICATIONS

This application claims priority to EP Application No. 22154952.0, having a filing date of Feb. 3, 2022, the entire contents of which are hereby incorporated by reference.

### FIELD OF TECHNOLOGY

The following relates to a method for calibrating an electronic assembly during a manufacturing process as well as a calibration arrangement comprising a calibration device and an electronic assembly to be calibrated.

### BACKGROUND

Electronic assemblies are frequently produced in large numbers and must satisfy various requirements in relation to their measurement accuracy. For this purpose, in a production line after an assembly and a programming of the assembly, a separate calibration station is introduced into the production line. In the calibration station, voltage and current values of the assembly defined using high-precision measuring instruments are predetermined, the difference and a calibration value therefrom are determined, and stored in firmware of the assembly for all subsequent measurements.

If, for example, in an analog assembly, a plurality of channels are present or a plurality of input circuits are installed, correspondingly many time-consuming measurements must be carried out since the calibration value can differ from channel to channel. In addition, it can be necessary to calibrate the channels in different measurement ranges. Since the calibration time scales massively with the number of channels of an assembly and the number of types of measurement and measurement ranges, each manufacturer strives to reduce these rate-determining times mostly for the production line.

With special knowledge it is possible to save individual calibration steps by intelligent combinatorics and thus optimize the calibration process. If a certain amplification of the analog input circuit is used, for example, in several types of measurement (voltage, current, temperature), in some cases it is sufficient to calibrate the amplification only in one of these types of measurement and use the calibration value internally for the other types of measurement and/or measurement ranges. However, this frequently results in a reduced or fluctuating accuracy of the circuits within an assembly.

### SUMMARY

An aspect relates to a method in which the duration of the calibration process is shortened, and a constant product quality is achieved in relation to a measurement accuracy.

According to a first aspect, embodiments of the invention relate to a method for calibrating an electronic assembly during a manufacturing process, comprising the steps:

determining a calibration value for the assembly which for a predefined input value gives a deviation between an actual output value output by the assembly and a predefined desired output value,

transmitting the calibration value to the assembly, and

storing the calibration value in the assembly,

wherein the calibration value of the assembly is determined by a machine learning method executed in a calibration device, and the machine learning method is trained by training data, which comprise historical calibration values of a plurality of assemblies of the same type and parameters of assemblies of the same type, which are dependent on the manufacturing process and/or express physical properties.

By the training data, physical relationships dependent on the manufacturing process and similarities in the manufacturing process of the assemblies can be modeled by the machine learning method and an expected value for the calibration value of an assembly to be calibrated can be determined. This expected value is output as calibration value by the machine learning method. By the machine learning method, the time expenditure for the calibration process can be reduced and thus, a cost saving in the production can be achieved with constant product quality. Long-term research and development findings in the manufacture of the assembly and/or components thereof can be used to optimize the production process.

In an embodiment, the training data additionally comprise parameters of at least one component of the assembly, which are dependent on the manufacturing process and/or express physical properties.

Thus, production-dependent and/or physical properties of components of the assembly can also be modeled in the machine learning method and therefore also take account of properties of supplied components. One or more components are manufactured, for example, in independent production processes in each case and can be subject to various influences. During the manufacture of the component, various materials or individual parts having various parameters such as batch number or thickness of a semiconductor structural element can be used. Thus, deeper insights in relation to product quality and component tendencies can be obtained.

In an embodiment, the training data additionally comprise parameters expressing physical properties of a manufacturing environment of the assembly of the same type.

Thus, the influence of various conditions in the manufacturing environment such as, for example, high or low ambient temperatures can be taken into account when determining the calibration value.

In an embodiment, the assembly comprises more than one assembly component to be calibrated and for each individual one of the assembly components the calibration value is determined by the calibration device and transmitted to the assembly.

This enables an individual calibration for each assembly component.

In an embodiment, a calibration query identifier is received from the assembly to be calibrated in the calibration device and the calibration value is transmitted depending on the transmitted calibration query identifier from the calibration device to the assembly to be calibrated, wherein the calibration query identifier can be assigned to at least one of the parameters of the training data.

The calibration query identifier is therefore transmitted from the assembly to the calibration device and initiates the determination of the calibration value. The calibration query identifier characterizes on the one hand the assembly for which the calibration value is requested and comprises at least one parameter of the assembly, which is dependent on the manufacturing process and/or expresses physical properties, wherein this parameter was used for training the machine learning method. The trained machine learning method determines the calibration value for the requesting assembly to be calibrated depending on the calibration query identifier.

In an embodiment, a calibration query identifier is received from the assembly to be calibrated in the calibration device and the calibration value is transmitted depending on the transmitted calibration query identifier from the calibration device to the assembly to be calibrated, wherein the calibration query identifier comprises a calibration value for one of the assembly components of the assembly to be calibrated, determined by measurement.

The calibration value determined by measurement for one of the assembly components of the assembly to be calibrated is transmitted as further input parameter to the trained machine learning method. As a result of this additional input value, the trained machine learning method can determine and output a calibration value with higher accuracy for the further components of the assembly.

In an embodiment, an accuracy of the calibrated assembly and/or the calibrated assembly component achieved with the stored calibration value is determined and depending on the determined accuracy, a quality value is assigned to the assembly and/or the calibrated assembly component.

Thus, the accuracy of the calibrated assembly or assembly components actually achieved with the stored calibration value can be determined and guaranteed to the user of the assembly. Thus, assemblies or assembly components can be specifically used for application with different requirements for the output accuracy depending on the quality value.

In an embodiment, the at least one calibration value stored in the assembly is only unlocked for use in the assembly after a successful unlock action.

Thus, a post-calibration of the assembly at the customer is possible.

In an embodiment, in each case one calibration value for one or one calibration value for a plurality of assembly components and/or in each case one calibration value for a measured variable or one calibration value for a plurality of different measured variables of the assembly component can be unlocked.

This enables a flexible and needs-based use of the assembly or components thereof in relation to the output accuracy.

In an embodiment, the at least one calibration value is activated by receiving a cryptographic key in the assembly which is specific for the assembly.

The cryptographic key on the one hand enables a tamper-proof storage of the calibration value in the assembly. By the cryptographic key, an improved measurement accuracy can be provided simply to a user as performance feature of the assembly.

In an embodiment in each case, one calibration value is determined by the calibration device for more than one different accuracy stage of the assembly and stored on the assembly, and on request, a calibration value different from the active calibration value on the assembly can be unlocked.

This enables a post-calibration of the assembly after the manufacturing process. As required, the calibration value for the desired accuracy stage can be loaded into the assembly.

According to a second aspect, embodiments of the invention relate to a calibration device for calibration of an electronic assembly during a manufacturing process, comprising:

a calibration unit, which is configured in such a manner to determine a calibration value for the assembly, which for a predefined input value gives a deviation between an actual output value output by the assembly and a predefined desired output value, and

an output unit, which is configured in such a manner to transmit the calibration value to the assembly,

wherein the calibration value of the assembly is determined by a machine learning method executed in the calibration device, and the machine learning method is trained by training data, which comprise historical calibration values of a plurality of assemblies of the same type and parameters of assemblies of the same type, which are dependent on the manufacturing process and/or express physical properties.

As a result of the machine learning method configured in the calibration unit, the calibration device enables a precise determination of the calibration value without needing to carry out measurements on the assembly to be calibrated. This shortens the calibration process during manufacture. The calibration device can be arranged spatially detached from the production plant. For example, the calibration device can be formed by a server in a server cloud and transmit the calibration value via a data connection to the production plant and further to the assembly. This makes it possible to use a central calibration device for several manufacturing processes also executed spatially separately, e.g. in different production plants.

According to a third aspect, embodiments of the invention relate to an electronic assembly, comprising:

an input interface, which is configured in such a manner to receive a calibration value for the assembly by a calibration device, which calibration value for a predefined input value gives a deviation between an actual output value output by the assembly and a predefined desired output value,

a storage unit, which is configured in such a manner to store the calibration value in the assembly, wherein the calibration value of the assembly is determined by a machine learning method executed in the calibration device and the machine learning method is trained by training data, which comprise historical calibration values of a plurality of assemblies of the same type and parameters of assemblies of the same type, which are dependent on the manufacturing process and/or express physical properties, and

an output interface, which is configured in such a manner to send a calibration query identifier from the assembly to the calibration device, wherein the calibration query identifier can be assigned to at least one of the parameters of the training data.

The electrical assembly is particularly flexible with regard to the calibration. Thus, the assembly can be calibrated during the manufacturing process by communication with the calibration device. The measurement accuracy or the calibration value of the assembly can be unlocked or changed after the manufacturing process.

A fourth aspect of embodiments of the invention relate to a calibration system, comprising a calibration device according to embodiments of the invention and at least one assembly to be calibrated, which is configured in such a manner to execute the method according to embodiments of the invention.

A fifth aspect of embodiments of the invention relate to a computer program product (non-transitory computer readable storage medium having instructions, which when executed by a processor, perform actions), comprising a non-volatile computer-readable medium, that can be loaded directly into a memory of a digital computer, comprising program code parts, which when the program code parts are executed by the digital computer, cause this to execute the steps of the method.

Unless specified otherwise in the following description, the terms “determine”, “transmit”, “store” and the like relate to actions and/or processes and/or processing steps, which change and/or generate data and/or convert the data into other data, wherein the data can be represented or be provided in particular as physical quantities, for example, as electrical pulses. The arrangement and components optionally contained therein such as, for example, the calibration unit or the storage unit and the like can comprise one or more processors. A processor can in particular be a main processor (central processing unit, CPU), a microprocessor or a microcontroller, for example, an application-specific integrated circuit or a digital signal processor, possibly combined with a storage unit for storing program commands etc.

A computer program product such as, for example, a computer program means, can, for example, be provided or delivered from a server in a network as a storage medium such as, for example, a memory card, USB stick, CD-ROM, DVD or also in the form of a downloadable file.

### BRIEF DESCRIPTION

Some of the embodiments will be described in detail, with reference to the following figures, wherein like designations denote like members, wherein:

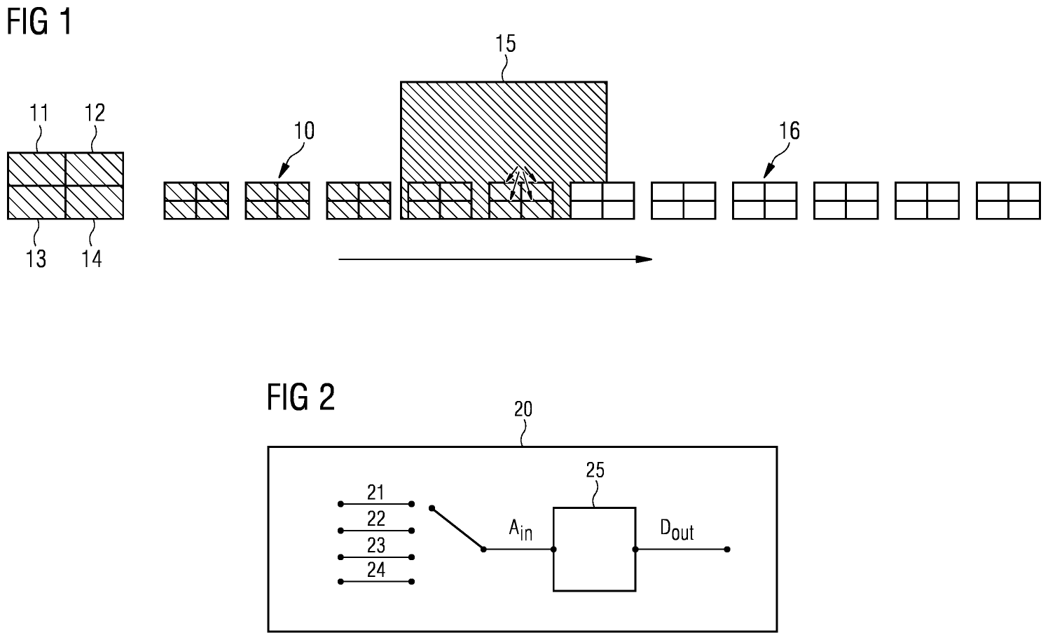

FIG. 1 shows an example of a conventional method for calibrating an assembly in schematic view;

FIG. 2 shows an example of an assembly with a plurality of input channels or measured variables in schematic view;

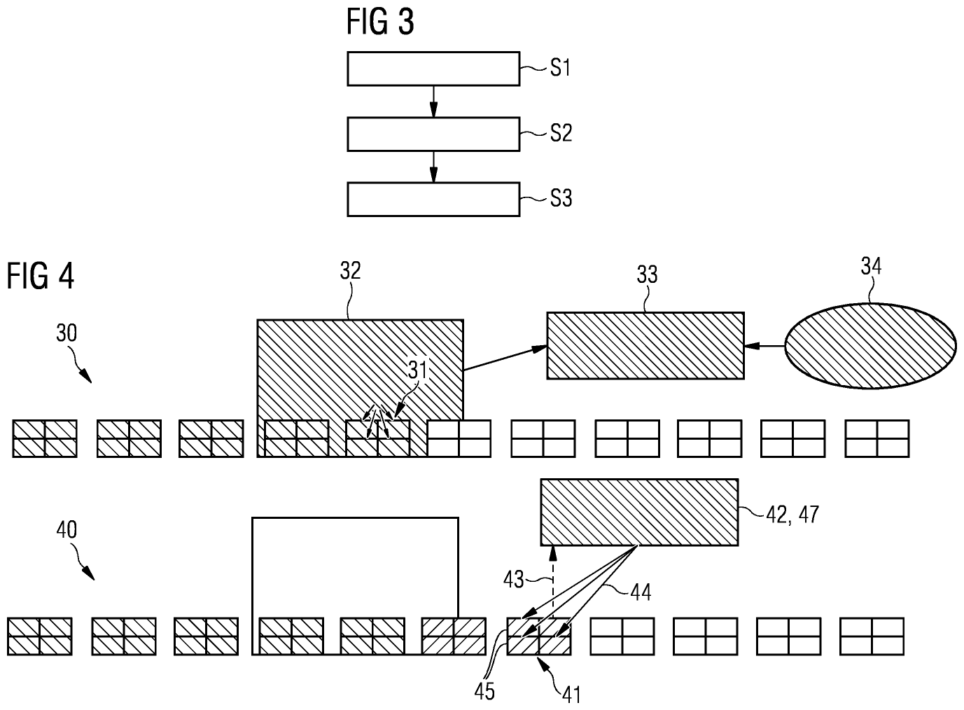

FIG. 3 shows a first exemplary embodiment of the calibration method as a flow diagram;

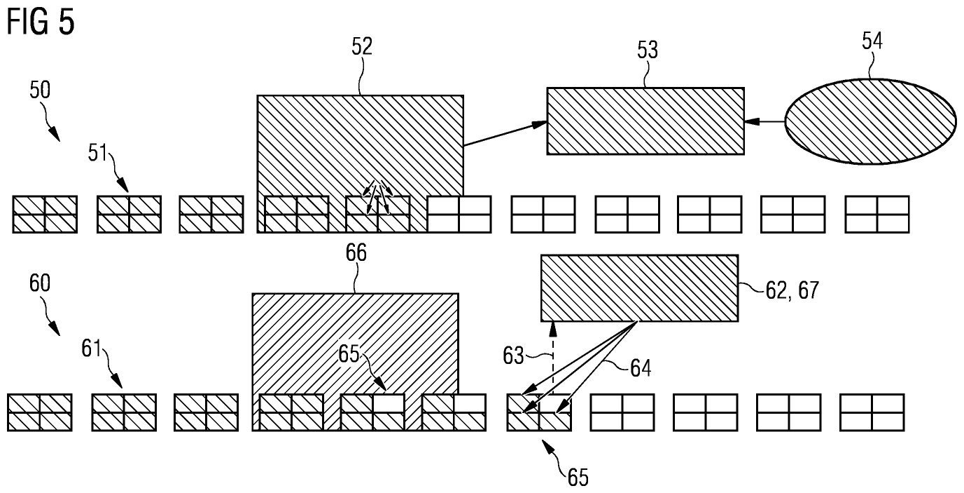

FIG. 4 shows a second exemplary embodiment of the calibration method within the manufacturing process in schematic view;

FIG. 5 shows a third exemplary embodiment of the calibration method with measured calibration value for an assembly component within the manufacturing process in schematic view;

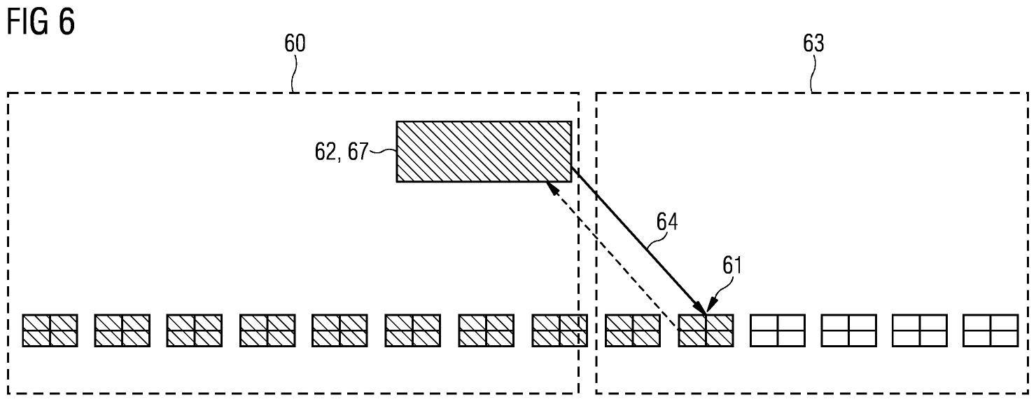

FIG. 6 shows a fourth exemplary embodiment of the calibration method with a request for a calibration value after the manufacturing process; and

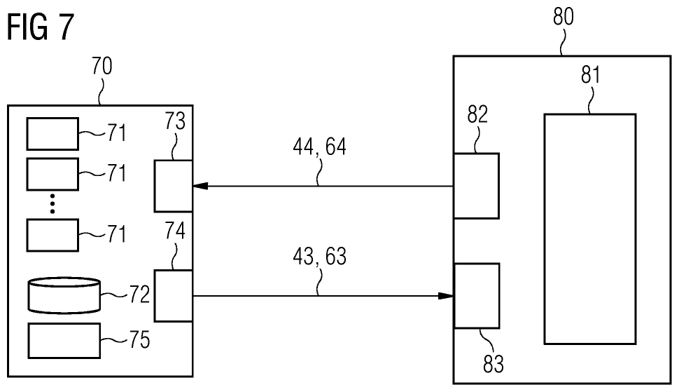

FIG. 7 shows an exemplary embodiment of a calibration arrangement in a block diagram.

### DETAILED DESCRIPTION

For illustration FIG. 1 shows a conventional calibration process during a manufacturing process. During the manufacturing process, mounted but uncalibrated assemblies 10, the uncalibrated state is shown by hatching, are fed to a calibration station 15. The assembly 10 consists of a plurality of, for example, four assembly components 11, 12, 13, 14. The assembly 10 can, for example, be an input assembly of a memory-programmable controller, which has a very high requirement in relation to the measurement accuracy to be achieved.

An assembly configured as input assembly 20 is shown in FIG. 2. The input assembly 20 comprises a plurality of assembly components, which are each configured as a channel 21, 22, 23, 24 of an input circuit, and an analog-digital converter 25. An analog input signal Aᵢₙ supplied via one of the channels 21, 22, 23, 24 is converted by the analog-digital converter 25 and a digital output signal Dout is output.

During calibration in the calibration station 15, a defined, predefined input quantity is applied as input value to the input of the input circuit, here channel 21, and a measured output value of the output signal is compared with a predefined desired value. Correction values are determined from the deviation between the measured output value with a defined input value and the desired value. These correction values are stored as calibration values in the assembly and used as correction values for the input circuits during subsequent operation of the memory-programmable controller. A calibrated assembly 16 with stored calibration values leaves the calibration station 15. In the Figures, calibrated assemblies are shown without hatching.

If, as shown, a plurality of channels 21, 22, 23, 24 are present in the input assembly 20 or a plurality of input circuits are installed, correspondingly many time-consuming measurements must be made since the calibration value can differ from channel to channel. In addition, it can be necessary to calibrate the channels in different measurement ranges. This results in high costs in the production of the assemblies.

By reference to FIG. 3, a calibration method for an electronic assembly during a manufacturing process is now explained, which enables a significant reduction on the time required for the calibration process, delivers a sufficient accuracy with regard to the calibration values, and includes an objective evaluation of the trained machine learning method used.

In a first process step S1 a calibration value is determined for the assembly. For a predefined input value the calibration value gives a deviation between an actual output value output by the assembly and a predefined desired output value. The calibration value of the assembly is determined by a machine learning method executed in a calibration device. The machine learning method is trained by training data, which comprise historical calibration values of a plurality of assemblies of the same type and parameters of assemblies of the same type, which are dependent on the manufacturing process and/or express physical properties. The training data can additionally comprise parameters of at least one k of the assembly, which are dependent on the manufacturing process and/or express physical properties and/or parameters of a production environment of the assembly of the same type, which express physical properties.

Then, see process step S2, the determined calibration value is transmitted to the assembly and stored in the assembly, see process step S3.

Since in the assemblies to be calibrated, manufacturing-dependent physical relationships and similarities exist due to the manufacturing process, the manufacturing environment or due to the material used for manufacture for individual components of the assembly, it is possible to model these relationships by the machine learning method and determine an expected value for the calibration value, which is then output as calibration value.

The machine learning method can, for example, be configured as a deep neural network, a generalized nonlinear regression model, or similar. The machine learning method

f(X)=ŷ≈y

determines from input data X ∈ [symbol] ^{p} estimated calibration values ŷ ∈ [symbol] ^{q}, wherein ŷ gives the predicted calibration values and y gives the correction values for physical calibration, i.e. by measurement of the actual output value and determining the deviation from a predefined desired output value for a predefined input value. In this case, in the p-dimensional input data space X it is possible to use both historical calibration values and further information relating to production parameters, environmental variables, manufacturing process of assembly components, in particular of supplier parts, as well as information relating to material used, for example, a position within a wafer of a semiconductor component and/or other influential parameters, in order to achieve the most precise possible prediction for the calibration values y.

Precise predictions of the calibration value are determined in the machine learning method configured for example as a neural network, by minimizing a distance dimension d(y, f (X)), for example, of a Euclidean distance or an Li distance by, for example, a gradient descent. These methods also cover the case of an under-identification (p<q) so that it is possible to infer a higher-dimensional output space y with a low-dimensional input space X.

In an embodiment, the trained learning method is evaluated objectively whereby the model f(.) trains with a test data set (X^{train}y^{train})and then evaluates the performance of the trained machine learning method with a test data set (X^{test}, y^{test}) with the aid of the distance dimension so that the expected deviation of the estimated and the actual calibration values can be objectively specified by d(y^{test}, f (X^{test})).

Depending on the configuration and definition of the input and output data space y and X of the machine learning method, i.e. depending on the training data used for training the machine learning method, a calibration value for the assembly, in each case a calibration value for an assembly component or a calibration value for a plurality of assembly components and/or in each case a calibration value for a measured variable or a calibration value for a plurality of different measured variables of the assembly component can be determined. Thus, various embodiments of the calibration method are possible.

FIG. 4 shows an embodiment of the calibration method in which the calibration values are primarily determined by the machine learning method in the calibration device and stored in the assembly. This is then followed only by a checking of the higher accuracy now achieved by the calibration values compared to a state without calibration values. In this case, data from the assemblies manufactured in the past as well as further external influential quantities are found in the input data space. The output data space on the other hand comprises all the calibration data of the assembly.

The upper part of FIG. 4 shows a training arrangement 30 for training a machine learning model 42 by historical calibration data 32, which is then used in the manufacturing process 40 to determine calibration data of assemblies to be calibrated.

In the training arrangement 30 historical calibration values 32 of a plurality of assemblies 31, which are of the same type as the assemblies 41 to be calibrated, calibration values of each assembly component 45 of the assembly 31, are determined. An untrained machine learning method 33 is trained using the historical calibration values 32, which were determined by measurement for example and using further data sources, in particular using parameters of the assembly 31, which are dependent on the manufacturing process 34 and/or express physical properties. The training data can additionally comprise parameters of at least one component of the assembly, which are dependent on the manufacturing process and/or express physical properties or additionally parameters of a manufacturing environment of the same type of assembly 31 which express physical properties.

In the calibration arrangement 40 an assembly 41 to be calibrated transmits a calibration query identifier 43 to the trained machine learning method 42 arranged in a calibration device. The calibration query identifier 43 can be assigned to at least one of the parameters of the training data. The calibration query identifier can, for example, be information relating to an installed component of the assembly and can be assigned to training data. The trained machine learning method 42 determines by the calibration query identifier 43 one or more calibration values 44 and transmits these to the assembly 41 to be calibrated. If the assembly 41 to be calibrated comprises more than one assembly component 45 to be calibrated, for each individual one of the assembly components 45 the calibration value is determined by the calibration device and transmitted to the assembly 41.

FIG. 5 shows a calibration arrangement 50 for a further embodiment of a calibration method 60 in which on the basis of individual calibration values determined by a conventional method, a trained machine learning method 62 now predicts the calibration values only for a part of the remaining components and thus shortens the calibration time proportionately. Accordingly, the input data space of the machine learning method 62 comprises data from assemblies manufactured in the past as well as data of the currently present assembly and optionally further external influential quantities. The output data space of the machine learning method 62 now only comprises a part of the calibration data of an assembly 61 to be calibrated.

In the training arrangement 50 historical calibration values 52 of a plurality of assemblies 51, which are of the same type as the assemblies 61 to be calibrated, calibration values of each assembly component of the assembly 51 are determined. An untrained machine learning method 53 is trained using the historical calibration values 52, which were determined, for example, by measurement, and using further data sources, in particular using parameters 54 of the assembly 51, which are dependent on the manufacturing process and/or express physical properties. The training data can additionally comprise parameters of at least one component of the assembly, which are dependent on the manufacturing process and/or express physical properties or additionally parameters of a manufacturing environment of the same type of assembly 31, which express physical properties.

In the manufacturing process 60 a calibration value is determined for one of the assembly components 65 of the assembly 61 to be calibrated in the conventional manner by a calibration station 66. The assembly 61 to be calibrated transmits a calibration query identifier 63 to the trained machine learning method 62 arranged in a calibration device, wherein the calibration query identifier 63 comprises the calibration value determined for the assembly components of the assembly to be calibrated. The trained machine learning method 62 determines, depending on the transmitted calibration query identifier 63, the calibration values 64 for the further assembly components of the assembly 65 to be calibrated and transmits these to the assembly 65.

FIG. 6 shows a variant of the calibration method from FIG. 4. A machine learning model 62 is trained according to the training arrangement 30. All the necessary calibration values of an assembly 61 to be calibrated during the manufacturing process 60 in a production plant are determined by a machine learning model 62, transmitted to the assembly 61 to be calibrated and stored there. This is followed by a verification of the accuracy in a final inspection of the manufacturing process for limiting values of the maximum attainable accuracy. The accuracy of the calibrated assembly 61 achieved with the stored calibration values and/or an achieved accuracy of the calibrated assembly components is determined and depending on the determined accuracy, a quality value is assigned to the assembly and/or the calibrated assembly component. However, the assembly is delivered with a lower accuracy class or quality class.

If necessary, in individual assembly components of the assembly 61 or even only individual measurement ranges of assembly components higher accuracy can be unlocked. To this end, a key is generated by the unique assembly identifier (F-ID) which individually unlocks the calibration values already present in the assembly. The at least one calibration value stored in the assembly 61 is only released for use in the assembly after a successful unlocking action. The calibration value can be unlocked for various time intervals. In each case, one calibration value for one assembly component or one calibration value for a plurality of assembly components and/or in each case one calibration value for one measured variable or one calibration value for a plurality of different measured variables of the assembly component can be unlocked. The at least one calibration value is activated by receiving a specific cryptographic key for the assembly 61 in the assembly 61. In each case, a calibration value is determined for more than one different accuracy stage of the assembly 61 by the calibration device and stored on the assembly and on request, a calibration value different from the active calibration value on the assembly can be unlocked.

It is advantageous in this case that individual assembly components, for example, channels or individual measurement ranges can be unlocked as required for a certain time interval and the user of the assembly 61 thus acquires more flexibility. In addition, the user of the assembly can save costs since, in the case of a high accuracy requirement for a few channels, he need not change to this accuracy class for all the channels.

FIG. 7 shows an exemplary embodiment of a calibration system, which comprises an exemplary embodiment of an electronic assembly 70 to be calibrated and an exemplary embodiment of a calibration device 80.

The electronic assembly 70 to be calibrated contains at least one assembly component 71, a storage unit 72, an input interface 73, and an output interface 74. The input interface 73 is configured in such a manner to receive a calibration value, for example, calibration value 44, 64 from FIGS. 4, 5, 6 for the assembly 70 by the calibration device 80, which for a predefined input value gives a deviation between an actual output value output by the assembly 70 or one of the assembly components 71 and a predefined desired output value. In this case, its own calibration value can be received for each of the assembly components 71 or for different measured variables or different measurement ranges of the assembly components 71.

The storage unit 72 is configured in such a manner to store the at least one calibration value 44, 64 received via the input interface 73 in the storage unit 73. The calibration value 44, 64 of the assembly 70 was determined by a machine learning method executed in the calibration device 80, wherein the machine learning method is trained by training data, which comprise historical calibration values of a plurality of assemblies of the same type as well as parameters of assemblies of the same type which are dependent on the manufacturing process and/or express physical properties.

The output interface 74 is configured in such a manner to generate a calibration query identifier 43, 63, see FIGS. 4 and 5, to which at least one of the parameters of the training data can be assigned or which comprises a calibration value determined by measurement for one of the assembly components 71 of the assembly 70 to be calibrated. The output interface 74 sends the calibration query identifier 43, 63 from the assembly 70 to the calibration device 80.

Each assembly component 71 is configured in such a manner to receive an input signal with an input value and to output an output signal with an output value. The output value is determined depending on the input signal and output corrected by the calibration value stored in the storage unit 72.

The calibration device 80 comprises a calibration unit 81, an output unit 82, and an input unit 83. The input unit 83 is arranged in such a manner to receive the calibration query identifier 43, 63.

The calibration unit 81 comprises at least one processor, on which the trained machine learning method is arranged and can be executed. The calibration unit 81 is configured in such a manner to determine the calibration value 44, 64 for the assembly 70 by the calibration query identifier 43, 63 or an identifier derived from the calibration query identifier 43, 63. The calibration query identifier 43, 63 is supplied from the input unit 83 as input value to the machine learning method in the calibration unit 81 and the determined calibration value 44, 64 is output to the output unit 82. The output unit 82 is configured in such a manner to transmit the calibration value 44, 64 to the assembly 70.

The calibration device 80 can also be configured in such a manner to execute the training of the machine learning method. To this end, training data are received in the calibration device 80, which comprise calibration values from a plurality of assemblies of the same type, also called historical calibration values, and parameters of assemblies of the same type which are dependent on the manufacturing process and/or express physical properties. In order to evaluate the machine learning method, calibration values determined for an assembly by the trained machine learning method can be compared with measured calibration data, and the machine learning method can be optimized. The training of the machine learning method can also be carried out in a device physically separate from the calibration device 80 and be introduced into the calibration device 80 after training.

Although the present invention has been disclosed in the form of embodiments and variations thereon, it will be understood that numerous additional modifications and variations could be made thereto without departing from the scope of the invention.

For the sake of clarity, it is to be understood that the use of “a” or “an” throughout this application does not exclude a plurality, and “comprising” does not exclude other steps or elements.

1. A method for calibrating an electronic assembly during a manufacturing process, comprising:
determining a calibration value for the assembly which for a predefined input value gives a deviation between an actual output value output by the electronic assembly and a predefined desired output value;
transmitting the calibration value to the electronic assembly; and
storing the calibration value in the electronic assembly;
wherein the calibration value of the electronic assembly is determined by a machine learning method executed in a calibration device, and the machine learning method is trained by training data, which includes historical calibration values of a plurality of assemblies of the same type and parameters of assemblies of the same type, which are dependent on the manufacturing process and/or express physical properties.

2. The method as claimed in claim 1, wherein the training data additionally comprise parameters of at least one component of the assembly of the same type, which are dependent on the manufacturing process and/or express physical properties.

3. The method as claimed in claim 1, wherein the training data additionally comprise parameters expressing physical properties of a manufacturing environment of the assembly of the same type.

4. The method as claimed in claim 1, wherein the electronic assembly comprises more than one assembly component to be calibrated and for each individual one of the assembly components the calibration value is determined by the calibration device and transmitted to the electronic assembly.

5. The method as claimed in claim 1, wherein a calibration query identifier is received from the electronic assembly to be calibrated in the calibration device and the calibration value is transmitted depending on the transmitted calibration query identifier from the calibration device to the electronic assembly to be calibrated, wherein the calibration query identifier can be assigned to at least one of the parameters of the training data.

6. The method as claimed in claim 1, wherein a calibration query identifier is received from the electronic assembly to be calibrated in the calibration device and the calibration value is transmitted depending on the transmitted calibration query identifier from the calibration device to the assembly to be calibrated, wherein the calibration query identifier comprises a calibration value for one of the assembly components of the assembly to be calibrated, determined by measurement.

7. The method as claimed in claim 1, wherein an accuracy of the calibrated assembly achieved with the stored calibration value and/or achieved accuracy of the calibrated assembly component is determined and depending on the determined accuracy is assigned a quality value of the electronic assembly and/or of the calibrated assembly component.

8. The method as claimed in claim 1, wherein the at least one calibration value stored in the electronic assembly is only released for use in the electronic assembly after a successful unlock action.

9. The method as claimed in claim 4, wherein in each case one calibration value for an assembly component or one calibration value for a plurality of assembly components and/or in each case one calibration value for a measured variable or one calibration value for a plurality of different measured variables of the assembly component can be unlocked.

10. The method as claimed in claim 8, wherein the at least one calibration value is activated by receiving a cryptographic key in the electronic assembly.

11. The method as claimed in claim 1, wherein in each case, one calibration value is determined by the calibration device for more than one different accuracy stage of the electronic assembly and stored on the electronic assembly, and on request, a calibration value different from the active calibration value on the electronic assembly can be unlocked.

12. A calibration device for calibration of an electronic assembly during a manufacturing process, comprising:
a calibration unit, which is configured in such a manner to determine a calibration value for the electronic assembly, which for a predefined input value gives a deviation between an actual output value output by the electronic assembly and a predefined desired output value, and
an output unit, which is configured in such a manner to transmit the calibration value to the electronic assembly; and
wherein the calibration value of the electronic assembly is determined by a machine learning method executed in the calibration device, and the machine learning method is trained by training data, which comprise historical calibration values of a plurality of assemblies of the same type and parameters of assemblies of the same type, which are dependent on the manufacturing process and/or express physical properties.

13. An electronic assembly, comprising:
an input interface, which is configured in such a manner to receive a calibration value for the electronic assembly by a calibration device, which calibration value for a predefined input value gives a deviation between an actual output value output by the electronic assembly and a predefined desired output value;
a storage unit, which is configured in such a manner to store the calibration value in the electronic assembly;
wherein the calibration value of the electronic assembly is determined by a machine learning method executed in the calibration device and the machine learning method is trained by training data, which comprise historical calibration values of a plurality of assemblies of the same type and parameters of assemblies of the same type, which are dependent on the manufacturing process and/or express physical properties; and
an output interface, which is configured in such a manner to send a calibration query identifier from the electronic assembly to the calibration device, wherein the calibration query identifier can be assigned at least one of the parameters of the training data.

14. A calibration system, comprising a calibration device as claimed in claim 12 and at least one assembly to be calibrated, which is configured in such a manner to execute the method.

15. A computer program product, comprising a computer readable hardware storage device having computer readable program code stored therein, said program code executable by a processor of a computer system to implement a method, comprising a non-volatile computer-readable medium, that can be loaded directly into a memory of a digital computer, comprising program code parts, which when the program code parts are executed by the digital computer, cause this to execute the steps of the method as claimed in claim 1.
